(19) United States
(12) Patent Application Publication
(10) Pub. No.: US 2017/0067142 A1
(43) Pub. Date: Mar. 9, 2017

(54) STRUCTURE AND FILM FORMATION METHOD

(71) Applicant: Shimadzu Corporation

(72) Inventors: Akina ICHIOKA, Kyoto (JP); Toshinori YOSHIMUTA, Kyoto (JP); Satoshi TOKUDA, Kyoto (JP); Daisuke IMAI, Kyoto (JP); Satoru OZAKI, Kyoto (JP); Yuu TOKUTAKE, Kyoto (JP)

(21) Appl. No.: 15/115,563

(22) PCT Filed: Jan. 20, 2015
(86) PCT No.: PCT/JP2015/051373

§ 371 Date: Jul. 29, 2016

(30) Foreign Application Priority Data
Jan. 30, 2014 (JP) 2014-015150
Jun. 16, 2014 (JP) 2014-123445

(51) Int. Cl. C23C 14/02; G02B 5/08; C23C 16/505; C23C 14/20; C23C 16/40

(52) U.S. Cl. CPC C23C 14/024; C23C 14/205; C23C 16/402; C23C 16/505; G02B 5/0808

(57) ABSTRACT

Provided is a structure configured such that even when resin, such as methacryl resin, exhibiting a low adhesion to a metal thin film is used, the resin and the metal thin film are firmly stacked in close contact with each other, and a film formation method capable of manufacturing a structure in which a metal thin film is, with a high adhesion, formed on a resin work exhibiting a low adhesion to the metal thin film, wherein the structure is configured such that an Al thin film 102 is, by sputtering, formed on a work W made of methacryl resin to form a stack of the work W and the Al thin film 102, and has a mixed region 101 of Al, Si, O, and C between the work W and the Al thin film 102. In the mixed region 101, Al is covalently bound to any one of Si, O, and C, or Al, Si, O, and C form a diffusion mixed layer.

### TECHNICAL FIELD

The present invention relates to a structure configured such that resin and a metal thin film are stacked one another and to a film formation method for forming a metal thin film on a resin work.

### BACKGROUND ART

For example, inorganic base materials such as glass have been typically used for optical components such as reflectors of headlights and meters in automobiles. However, with the demand for weight reduction for, e.g., improvement in fuel consumption of automobiles, these inorganic base materials have been replaced with resin base materials. Moreover, although plating has been often used as a typical metal film formation method, such a method has been recently replaced with a dry process such as sputtering in order to reduce an environmental load. For the purpose of providing mirror finish or the texture of metal, a film is formed on an injection-molded resin component by sputtering using metal such as aluminum as a target.

After film formation by sputtering, e.g., a silicon oxide protection film is often formed by plasma CVD to protect against oxidation of the metal film or scratches of the surface of the metal film. That is, the work is, after film formation by sputtering, delivered to another film formation device, and then, plasma CVD using monomer gas such as hexamethyldisiloxane (HMDSO) is performed in a chamber of the film formation device. In this manner, the protection film is formed on the film surface formed by sputtering.

The device has been proposed, which is configured such that film formation by sputtering, and composite or polymerized film formation are performed in the same chamber. Patent Document 1 discloses a film formation device configured such that an electrode for sputtering and an electrode for composite or polymerized film formation are arranged apart from each other by a predetermined distance. In this film formation device, a work and the sputtering electrode are first arranged to face each other. After inert gas is introduced into the chamber, direct current is applied to the sputtering electrode to perform film formation by sputtering. Then, the work is moved such that the work and the electrode for composite or polymerized film formation are arranged to face each other. After monomer gas such as HMDSO is introduced into the chamber, high-frequency voltage is applied to the electrode for composite or polymerized film formation to perform composite or polymerized film formation. The film formation device of Patent Document 1 is configured such that a shutter is disposed above a target not in use.

### PRIOR ART DOCUMENT

### Patent Document

Patent Document 1: JP-A-2011-58048

### SUMMARY OF THE INVENTION

### Problems to be Solved by the Invention

In particular, methacryl (PMMA) resin is, as a work material on which a film is formed by sputtering as described above, often used for mirrors etc. because the methacryl resin is inexpensive and exhibits a high degree of transparency. Moreover, since such a high degree of transparency provides a touch of class, the demand for use in, e.g., containers of cosmetic products has been increased. However, the methacryl resin exhibits a low adhesion to a metal thin film, and for this reason, it is difficult to form a suitable metal thin film on the surface of the methacryl resin.

That is, in the case of forming a metal thin film on methacryl resin by sputtering, high-energy metal particles enter the surface of the methacryl resin. Thus, molecular chains of the methacryl resin are broken, leading to embrittlement of the surface of the methacryl resin. The phenomenon occurs, in which the metal thin film is detached from such an embrittled portion of the surface of the methacryl resin.

FIG. 19 is a graph of a wide scan spectrum obtained in such a manner that the element composition of the methacryl resin exposed after detachment of the Al film is measured by X-ray photoelectron spectroscopy (XPS). The horizontal axis in FIG. 19 represents binding energy, and the vertical axis in FIG. 19 represents counts per second (CPS).

As shown in the graph, the O1s peak and the O KLL peak of oxygen (O) as a component of the methacryl resin are detected, and the C1s peak of carbon (C) as a component of the methacryl resin is detected. On the other hand, no peaks of Al2p and Al2s of aluminum (Al) are detected. When element shift due to chemical binding does not occur, the following peaks are detected: the C1s peak at about 274.5 eV; the O1s peak at about 531.0 eV; the Al2p peak at about 72.9 eV; and the Al2s peak at about 118 eV.

The detection depth in XPS analysis is within a range of about several nanometers (nm) to about 10 nm from the surface. Thus, the embrittled portion of the surface of the methacryl resin is exposed due to Al film detachment. Al is present in the region positioned deeper than the embrittled portion exposed after Al film detachment, and no Al is detected in XPS analysis.

The inventor(s) of the present invention has found that the above-described embrittled portion becomes particularly noticeable in the case of a high power being applied to the sputtering electrode, e.g., the case of applying a power of equal to or higher than 25 watts to every square centimeter of the surface area of the target material of the sputtering electrode at the sputtering.

The adhesion may be improved in such a manner that a binder layer is formed on the surface of the methacryl resin by, e.g., a wet process. However, this leads not only to a complicated process but also to an adverse effect on natural environment due to waste etc.

The present invention has been made to solve the above-described problem. The present invention is intended to provide a structure configured such that even when resin, such as methacryl resin, exhibiting a low adhesion to a metal thin film is used, the resin and the metal thin film are firmly stacked in close contact with each other, and to provide a film formation method capable of manufacturing a structure in which a metal thin film is, with a high adhesion, formed on a resin work exhibiting a low adhesion to the metal thin film.

### Solutions to the Problems

A first aspect of the invention is intended for a structure in which resin and a metal thin film are stacked one another. The structure includes a mixed region which is formed between the resin and the metal thin film and in which atoms forming the metal thin film and Si are mixed together.

According to a second aspect of the invention, in the mixed region, at least one of O or C is mixed in addition to the atoms forming the metal thin film and Si.

According to a third aspect of the invention, the resin is methacryl resin.

According to a fourth aspect of the invention, the metal thin film is formed by sputtering.

According to a fifth aspect of the invention, the metal thin film is formed of Al or metal containing Al as a main component.

According to a sixth aspect of the invention, when the metal thin film is formed by the sputtering after plasma processing is performed under the presence of Si, a mixed region where Al and Si are mixed together is formed.

According to a seventh aspect of the invention, in the mixed region, the atoms forming the metal thin film are covalently bound to any one of Si, O, and C, or the atoms forming the metal thin film and any one of Si, O, and C form a diffusion alloy layer.

According to an eighth aspect of the invention, a mixed layer of Si, O, and C, a compound layer containing Si oxide, and a mixed layer of the atoms forming the metal thin film, Si, and O are, in this order, stacked one another between the resin and the metal thin film.

According to a ninth aspect of the invention, a mixed layer of Si, O, and C and a mixed layer of the atoms forming the metal thin film, Si, and O are, in this order, stacked one another between the resin and the metal thin film.

According to a tenth aspect of the invention, a protection film is further formed on the surface of the metal thin film.

According to an eleventh aspect of the invention, the protection film is a Si oxide-based protection film.

A twelfth aspect of the invention is intended for a method for forming a metal thin film on a resin work. The method includes the plasma processing step of performing plasma processing for the rein work under the presence of Si, and the sputtering film formation step of using a metal target material to perform sputtering film formation for the work.

According to a thirteenth aspect of the invention, the method further includes the work delivery step of delivering the work into a chamber, the inert gas supply step of supplying inert gas containing Si into the chamber, the CVD step of forming a film containing Si by plasma CVD, and the sputtering film formation step of forming a metal thin film by sputtering.

According to a fourteenth aspect of the invention, the method further includes the work delivery step of delivering the work into a chamber, the oxygen supply step of supplying oxygen containing Si into the chamber, the CVD step of forming a film containing Si by plasma CVD, and the sputtering film formation step of forming a metal thin film by sputtering.

According to a fifteenth aspect of the invention, a plasma CVD film formation step using Si oxide is performed before the plasma processing step or between the plasma processing step and the sputtering film formation step.

According to a sixteenth aspect of the invention, the method further includes, after the sputtering film formation step, the raw material gas supply step of supplying raw material gas into the chamber, and the step of forming a film containing the raw material gas by plasma CVD.

### Effects of the Invention

According to the first to sixteenth aspects of the invention, even when resin, such as methacryl-based resin, exhibiting a low adhesion to a metal thin film is used, the resin and the metal thin film are firmly stacked in close contact with each other.

In particular, according to the tenth, eleventh, and sixteenth aspects of the invention, metal thin film formation by sputtering and protection film formation by plasma CVD can be successively performed in a short amount of time in the same chamber.

### BRIEF DESCRIPTION OF THE DRAWINGS

FIG. 1 is a schematic diagram of a film formation device configured to perform a film formation method according to the present invention.

FIG. 2 is a block diagram of a control system of the film formation device of the present invention.

FIG. 3 is a flowchart of film formation operation.

FIGS. 4(a) to 4(d) are schematic views for the purpose of describing the state of film formation on a work W.

FIG. 5 is a photograph of the cross section of the region extending from the work W to an Al thin film 102 in the case of performing film formation by the film formation method of the present invention, the photograph being taken by a transmission electron microscope.

FIG. 6 is a graph of TEM-EDX analysis results of a point 1-1 of FIG. 5.

FIG. 7 is a graph of TEM-EDX analysis results of a point 1-2 of FIG. 5.

FIG. 8 is a graph of TEM-EDX analysis results of a point 1-3 of FIG. 5.

FIG. 9 is a photograph of the cross section of the region extending from a work to an Al thin film in the case of performing film formation by a conventional film formation method, the photograph being taken by a transmission electron microscope.

FIG. 10 is a graph of TEM-EDX analysis results of a point 2-1 of FIG. 9.

FIG. 11 is a graph of TEM-EDX analysis results of a point 2-2 of FIG. 9.

FIG. 12 is a graph of TEM-EDX analysis results of a point 2-3 of FIG. 9.

FIG. 13 is a flowchart of film formation operation of a second embodiment.

FIGS. 14(a) to 14(e) are schematic views for the purpose of describing the state of film formation on a work W.

FIG. 15 is a flowchart of film formation operation of a third embodiment.

FIGS. 16(a) to 16(e) are schematic views for the purpose of describing the state of film formation on a work W.

FIG. 17 is a schematic diagram of a film formation device configured to perform a film formation method according to a fourth embodiment of the present invention.

FIG. 18 is a flowchart of film formation operation of the fourth embodiment.

FIG. 19 is a graph of XPS analysis results of a portion of methacryl resin from which a film is detached.

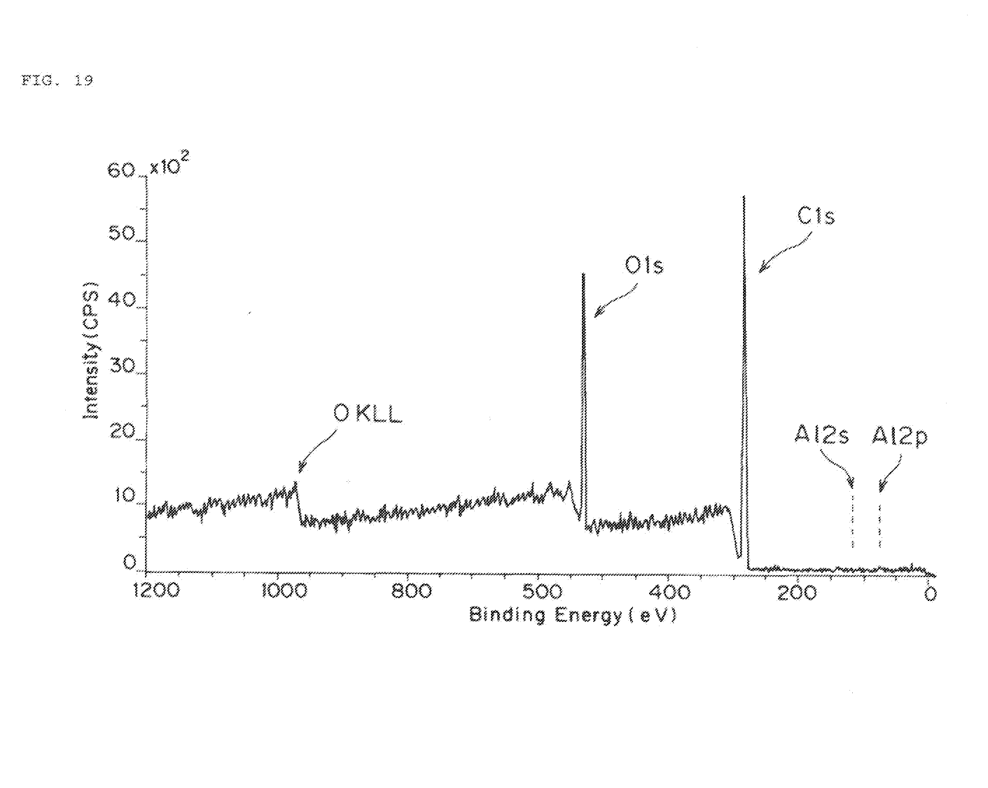

### DESCRIPTION OF EMBODIMENTS

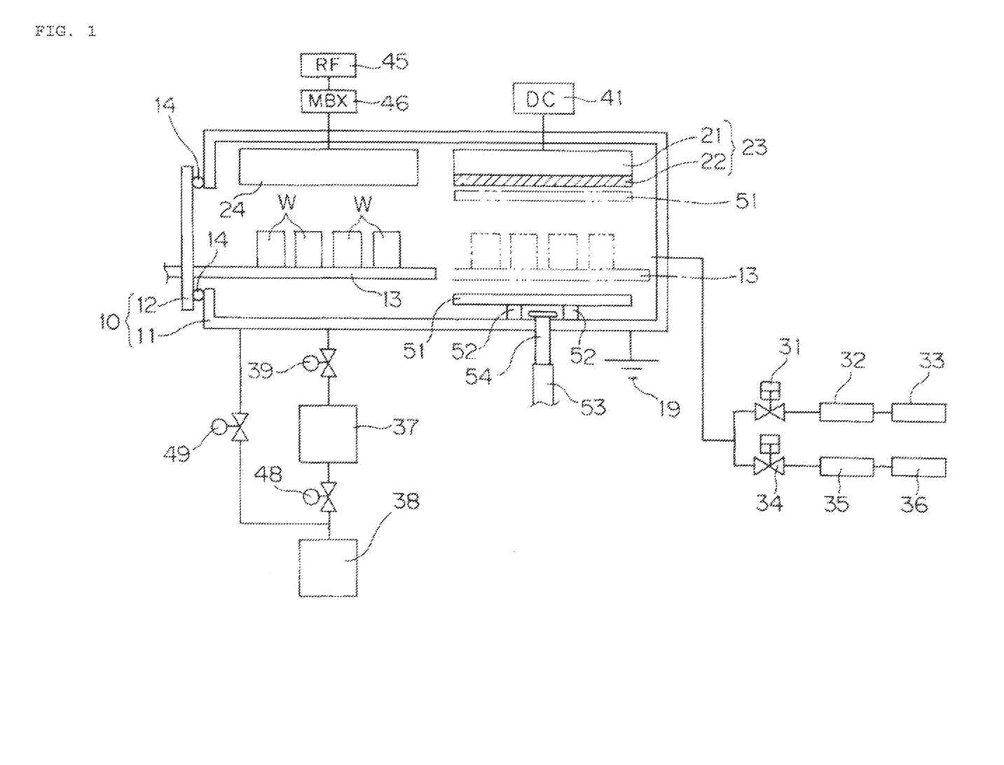

Embodiments of the present invention will be described below with reference to drawings. FIG. 1 is a schematic diagram of a film formation device configured to perform a film formation method according to the present invention.

The film formation device of the present embodiment is configured to perform, for a work W made of resin, film formation by sputtering and film formation by plasma CVD. Note that methacryl resin is used as the material of the work W. The methacryl resin is the formal name of resin generally called “acrylic resin,” and may be called “polymethyl methacrylate (PMMA)” or “acrylic glass.” The methacryl resin has characteristics such as inexpensive and a high degree of transparency, and on the other hand, exhibits a low adhesion to a metal thin film.

The film formation device includes a film formation chamber 10 having a main body 11 and an openable portion 12. The openable portion 12 is movable between a delivery position at which the injection-molded resin work W is delivered into the film formation chamber 10 and a closed position at which the film formation chamber 10 is tightly closed via a packing 14 provided between the main body 11 and the openable portion 12. When the openable portion 12 has moved to the delivery position, an opening is formed at a side surface of the film formation chamber 10 so that the work W can be delivered into the film formation chamber 10 or delivered out of the film formation chamber 10 through the opening. Moreover, a work mount 13 on which the work W is mounted is disposed to penetrate through a passage hole formed at the openable portion 12. The work mount 13 is movable relative to the openable portion 12 with the work W being mounted on the work mount 13.

The film formation device includes a sputtering electrode 23 having an electrode portion 21 and a target material 22. The sputtering electrode 23 is, via a not-shown insulating member, attached to the main body 11 of the film formation chamber 10. Note that the main body 11 forming the film formation chamber 10 is connected to the ground 19. The sputtering electrode 23 is connected to a direct current power source 41.

Note that a power source capable of applying direct current voltage to the sputtering electrode 23 such that a power of equal to or higher than 25 watts is applied to every square centimeter of the surface area of the target material 22 is used as the direct current power source 41. That is, the direct current power source 41 applies, as the power to be applied to the sputtering electrode 23, a power of equal to or higher than 25 watts to every square centimeter of the surface area of the target material 22. Aluminum (Al) is used as the target material 22. Note that an Al alloy may be used instead of Al.

The film formation device further includes a CVD electrode 24. The CVD electrode 24 is, as in the sputtering electrode 23, attached to the main body 11 of the film formation chamber 10 via a not-shown insulating member. The CVD electrode 24 is also connected to a matching box 46 and a high-frequency power source 45.

Note that, e.g., a power source configured to generate a high frequency of about tens of megahertz (MHz) can be used as the high-frequency power source 45. The high frequency descried herein indicates a frequency of equal to or higher than 20 kilohertz (kHz).

The main body 11 forming the film formation chamber 10 is, via an on-off valve 31 and a flow control valve 32, connected to a supply 33 of inert gas such as argon. Moreover, the main body 11 forming the film formation chamber 10 is, via an on-off valve 34 and a flow control valve 35, connected to a supply 36 of raw material gas. HMDSO is used as the raw material gas. Note that as long as the raw material gas is the gas containing Si, hexamethyldisilazane (HMDS) may be used instead of HMDSO, for example. Further, the main body 11 forming the film formation chamber 10 is, via an on-off valve 39, connected to a turbo-molecular pump 37. The turbo-molecular pump 37 is connected to an auxiliary pump 38 via an on-off valve 48. In addition, the auxiliary pump 38 is also connected to the main body 11 of the film formation chamber 10 via an on-off valve 49.

Note that a turbo-molecular pump whose maximum exhaust velocity is equal to or greater than 300 liters per second is used as the turbo-molecular pump 37.

The film formation device further includes a shutter 51 configured to move, by driving of an air cylinder 53, up and down between a contact position at which the shutter 51 contacts the sputtering electrode 23 to cover the target material 22 as indicated by a virtual line of FIG. 1 and a retracted position at which the shutter 51 is supported by a support 52 in the vicinity of a bottom portion of the film formation chamber 10 as indicated by a solid line of FIG. 1. The shutter 51 is formed of the material functioning as both of a conductor such as metal and a non-magnetic body.

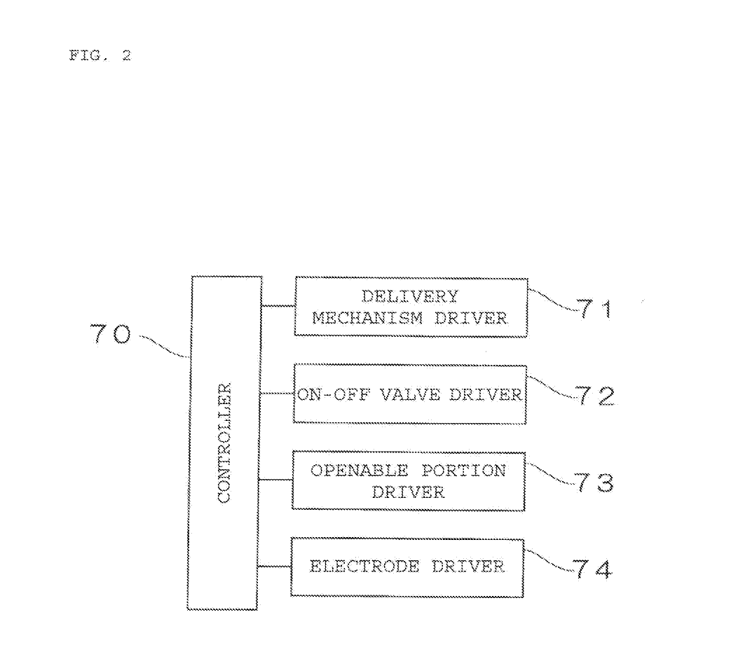

FIG. 2 is a block diagram of a control system of the film formation device of the present invention.

The film formation device includes a controller 70 configured to control the entire device. The controller 70 includes a CPU configured to execute logical operation, a ROM configured to store an operation program required for device control, and a RAM configured to temporarily store data etc. in control. The controller 70 is also connected to a delivery mechanism driver 71 configured to drive and control a delivery mechanism for moving the work mount 13 illustrated in FIG. 1, an on-off valve driver 72 configured to control opening/closing of, e.g., the on-off valves 31, 34, 39, 48, 49, an openable portion driver 73 configured to control opening/closing of the openable portion 12, and an electrode driver 74 configured to drive and control the sputtering electrode 23 and the CVD electrode 24.

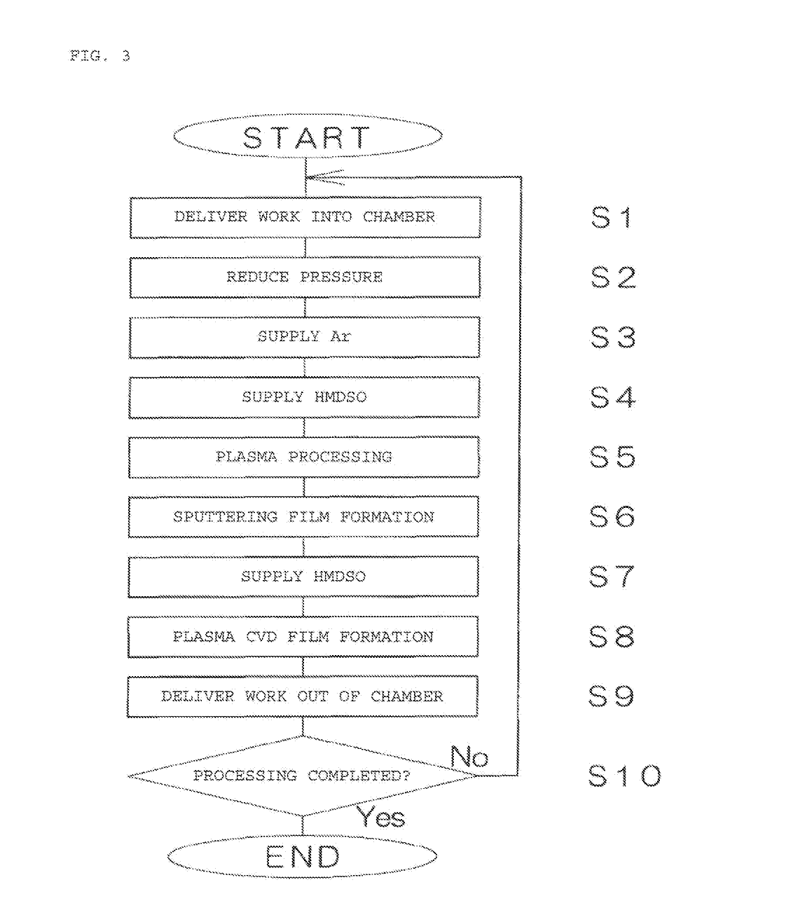

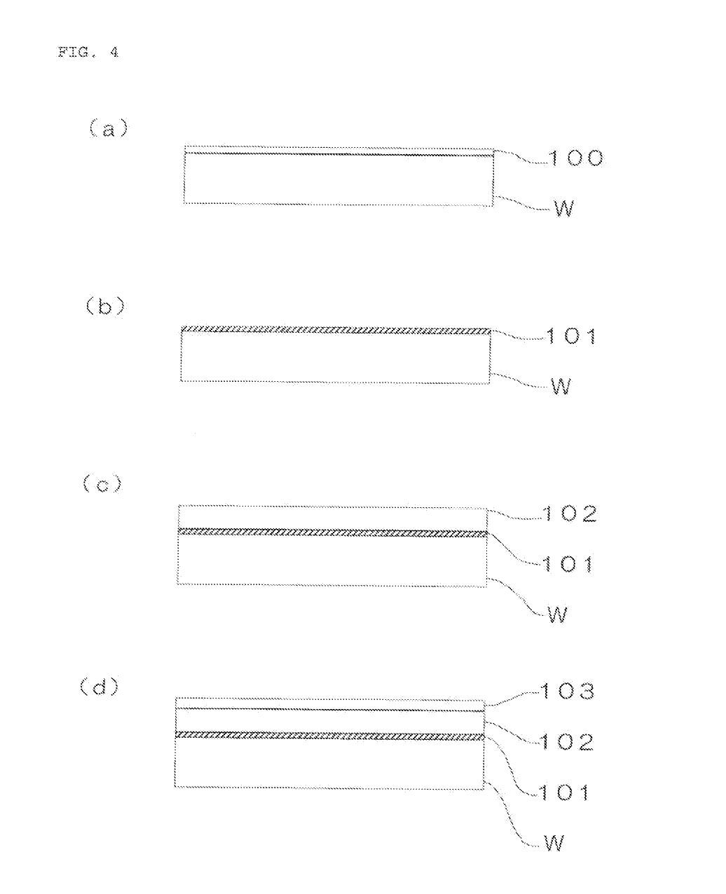

Next, film formation operation by the film formation device having the above-described configuration will be described. FIG. 3 is a flowchart of the film formation operation. Moreover, FIGS. 4(a) to 4(d) are schematic views for the purpose of describing the state of film formation on the work W.

When the film formation operation is performed by the film formation device, the injection-molded work W is delivered out of an injection molding machine, and then, is delivered into the film formation chamber 10 (step S1). At this point, the openable portion 12 is moved to the delivery position, and then, the work W mounted on the work mount 13 is arranged so as to face the CVD electrode 24 in the film formation chamber 10 as indicated by a solid line of FIG. 1. Moreover, as indicated by the virtual line of FIG. 1, the shutter 51 is at the contact position at which the shutter 51 contacts the sputtering electrode 23 to cover the target material 22. In this state, a cylinder rod 54 of the air cylinder 53 is in a retracted state in which the cylinder rod 54 is retracted into a main body of the air cylinder 53.

Next, the openable portion 12 is moved to the closed position, and then, the inner pressure of the film formation chamber 10 is reduced to a low vacuum of about 0.1 to 1 pascal (step S2). Before pressure reduction by the turbo-molecular pump 37, the auxiliary pump 38 such as a rotary pump is used to perform pressure reduction to about 100 pascals at high speed. Subsequently, the turbo-molecular pump 37 whose maximum exhaust velocity is equal to or greater than 300 liters per second is used so that the inner pressure of the film formation chamber 10 can be reduced to a low vacuum of about 0.1 to 1 pascal in about 20 seconds.

Next, the on-off valve 31 opens to supply argon as inert gas from the inert gas supply 33 into the film formation chamber 10, and then, the film formation chamber 10 is filled with the argon such that the degree of vacuum in the film formation chamber 10 reaches 0.5 to 3 pascals (step S3). Note that inert gas other than argon may be used, and depending on conditions, oxygen or nitrogen may be used instead of argon. Then, the on-off valve 34 opens to supply HMDSO from the raw material gas supply 36 into the film formation chamber 10 (step S4).

In this state, plasma processing is performed (step S5). At this point, a high-frequency voltage of about 400 W is applied from the high-frequency power source 45 to the CVD electrode 24 via the matching box 46. Moreover, HMDSO is supplied from the raw material gas supply 36 at a flow rate of about 5 sccm, and argon is supplied from the inert gas supply 33 at a flow rate of about 100 sccm. Such plasma processing is completed in about several tens of seconds. In this state, a compound layer 100 of Si, O, and C generated from HMDSO etc. is formed on the surface of the work W made of the methacryl resin, as illustrated in FIG. 4(a).

Next, sputtering film formation is performed (step S6). At this point, as indicated by a virtual line of FIG. 1, the work W mounted on the work mount 13 is moved to face the sputtering electrode 23 in the film formation chamber 10. Moreover, as indicated by the solid line of FIG. 1, the shutter 51 is at the retracted position in the vicinity of the bottom portion of the film formation chamber 10. In the case of performing the sputtering film formation, direct current voltage is applied from the direct current power source 41 to the sputtering electrode 23. Thus, a thin film of Al as the target material 22 is formed on the surface of the work W by the sputtering phenomenon.

In the above-described state, Al first contacts, by the sputtering phenomenon, the compound layer 100 of Si, O, and C generated from HMDSO etc. Thus, as illustrated in FIG. 4 (b), Al is covalently bound to Si, O, and C in the compound layer 100, or Al, Si, O, and C form a diffusion mixed layer in the compound layer 100. Thus, a mixed region 101 where Al, Si, O, and C are mixed together is formed. At this point, the thickness of the mixed region 101 is about several angstroms to about several nanometers equivalent to several atomic layers.

By continuing the sputtering film formation, the Al thin film 102 is formed on the mixed region 101 as illustrated in FIG. 4 (c). The thickness of the Al thin film 102 is about 150 nanometers.

Note that at this sputtering film formation step, direct current voltage is applied from the direct current power source 41 to the sputtering electrode 23 such that a power of equal to or higher than 25 watts is applied to every square centimeter of the surface area of the target material 22 of the sputtering electrode 23. Thus, even in the case of a low vacuum in the film formation chamber 10, the Al thin film 102 is suitably formed on the surface of the resin work W.

After the sputtering film formation performed by the above-described steps has been completed, film formation by plasma CVD using Si oxide is subsequently performed. In the case of performing the plasma CVD film formation, the work W mounted on the work mount 13 is moved to face the CVD electrode 24 in the film formation chamber 10, as indicated by the solid line of FIG. 1. Moreover, as indicated by the virtual line of FIG. 1, the shutter 51 is at the contact position at which the shutter 51 contacts the sputtering electrode 23 to cover the target material 22.

In this state, the on-off valve 34 opens to supply HMDSO as raw material gas from the raw material gas supply 36 into the film formation chamber 10, and as a result, the degree of vacuum in the film formation chamber 10 reaches 0.1 to 10 pascals (step S7). Then, high-frequency voltage is applied from the high-frequency power source 45 to the CVD electrode 24 via the matching box 46, and in this manner, the plasma CVD film formation is performed (step S8). As illustrated in FIG. 4 (d), a protection film 103 is, as a result of the plasma CVD reaction using the raw material gas, deposited on the surface of the work W (i.e., the surface of the Al thin film 102).

After the plasma CVD film formation has been completed, the film formation chamber 10 is vented. Subsequently, the work mount 13 is moved with the openable portion 12 being at the delivery position, and then, the work W mounted on the work mount 13 is, after the film formation, delivered out of the film formation chamber 10 (step S9).

Then, it is determined whether or not the processing for all of the works W has been completed (step S10). When the processing for all of the works W has been completed, the device is stopped. On the other hand, when there is an unprocessed work(s) W, the process returns to step S1.

Note that in the case of continuously performing the above-described processing, Si used in the plasma CVD film formation remains in the film formation chamber 10. Depending on the remaining amount of Si, the compound layer 100 of Si, O, and C might be able to be formed at the plasma processing step (step S5) even when no Si is additionally supplied. Thus, the HMDSO supply step at step S4 may be skipped.

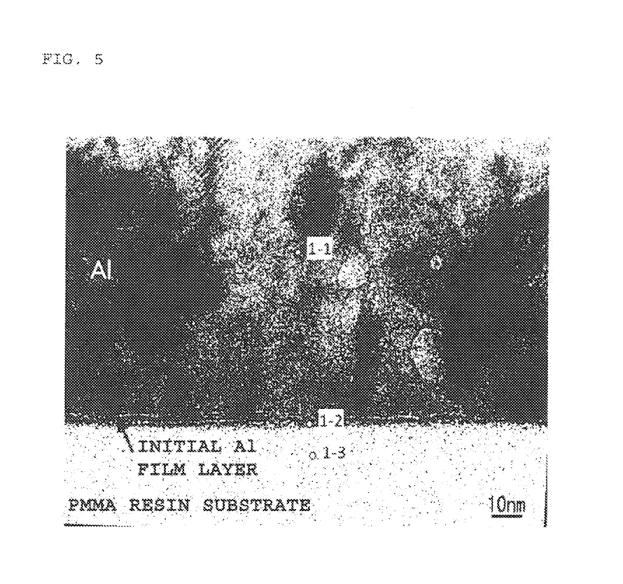

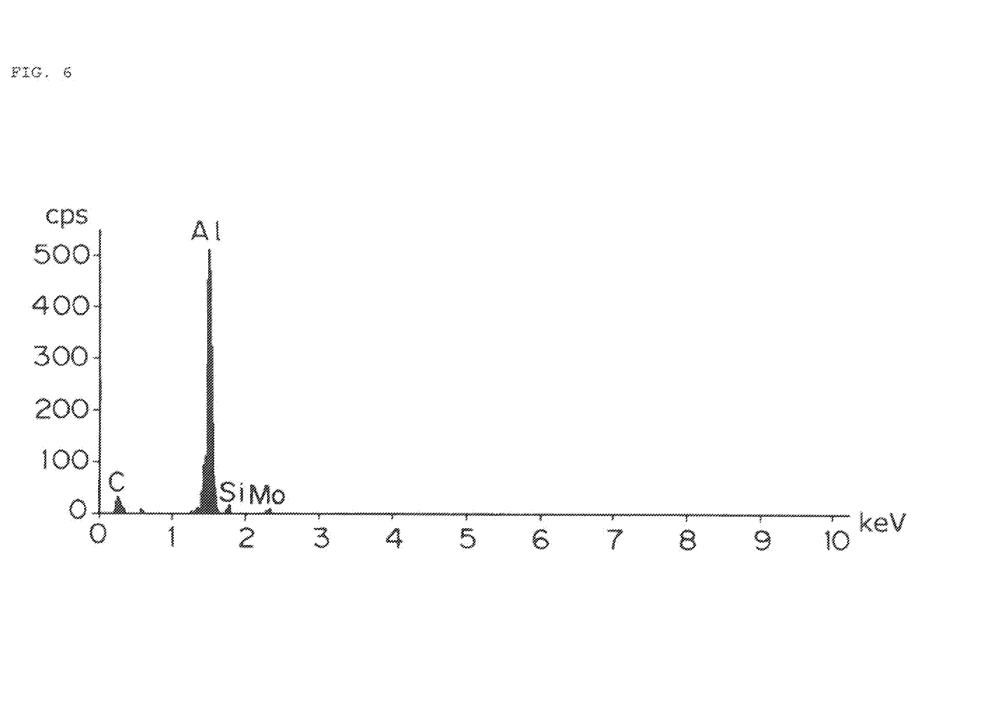

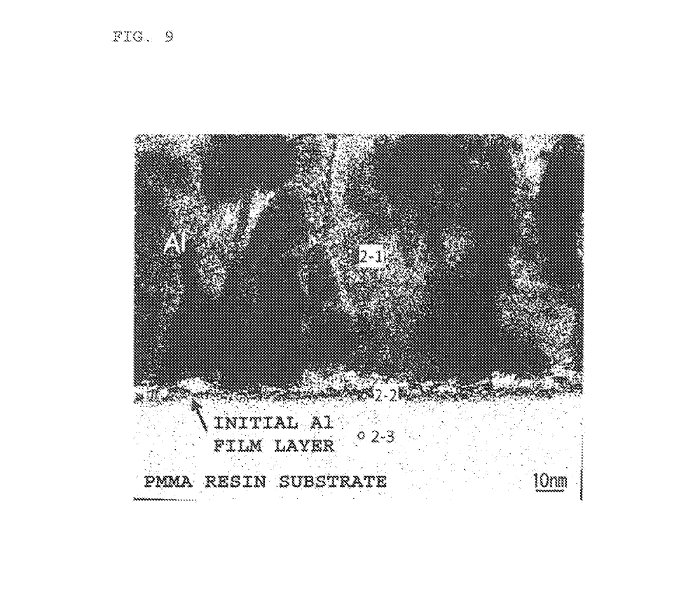

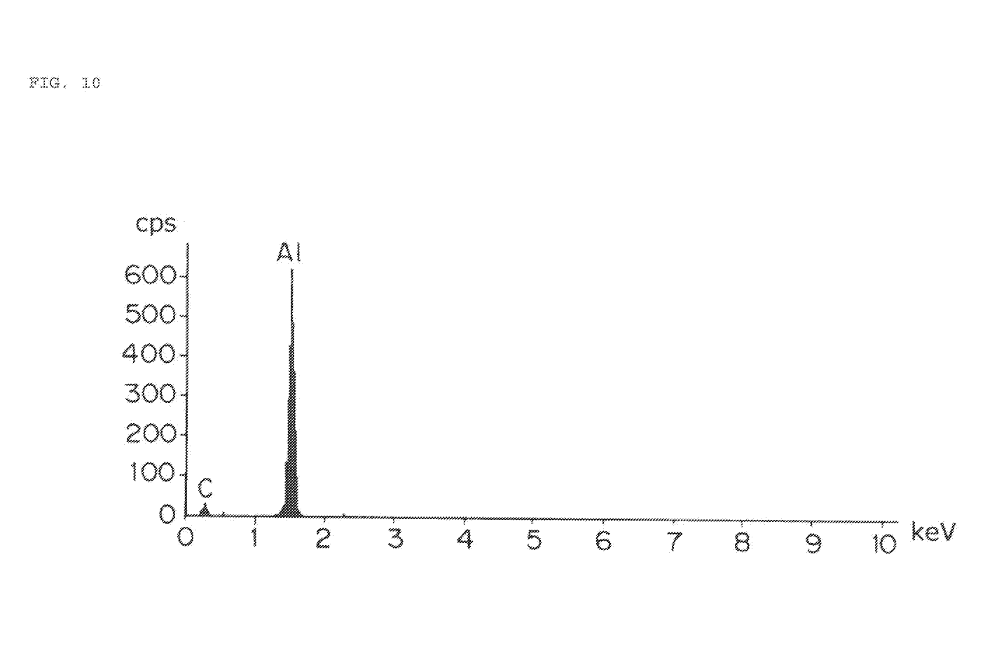

FIG. 5 is a photograph of the cross section of the region extending from the work W to the Al thin film 102 as illustrated in FIG. 4(d) in the case of performing film formation by the film formation method of the present invention, the photograph being taken by a transmission electron microscope (TEM). Moreover, FIGS. 6 to 8 are graphs of energy dispersive X-ray spectrometric (TEM-EDX) analysis results of points 1-1, 1-2, 1-3 of FIG. 5. Further, FIG. 9 is a photograph of the cross section of the region extending from a work W to an Al thin film 102 in the case of performing film formation by a conventional film formation method, the photograph being taken by a transmission electron microscope (TEM). In addition, FIGS. 10 to 12 are graphs of energy dispersive X-ray spectrometric (TEM-EDX) analysis results of points 2-1, 2-2, 2-3 of FIG. 9.

Note that in FIGS. 6 to 8 and FIGS. 10 to 12, the horizontal axis represents fluorescent X-ray energy, and the vertical axis represents fluorescent X-ray strength. The unit of the fluorescent X-ray energy is kilo electron volt (keV). Moreover, the fluorescent X-ray strength indicates how many fluorescent X-rays having a certain level of energy are detected, and the unit of the fluorescent X-ray strength is counts per second (CPS). In these figures, elemental analysis can be made based on a fluorescent X-ray energy level at which a peak is detected. Note that the full scale count value for the vertical axis is different among the above-described figures.

The point 1-1 in FIG. 5 and the point 2-1 in FIG. 9 correspond to the Al thin film 102 illustrated in FIG. 4(d). At these points, Al is mainly detected, and there is no difference between the case of applying the present invention as illustrated in FIG. 5 and the conventional case of FIG. 9.

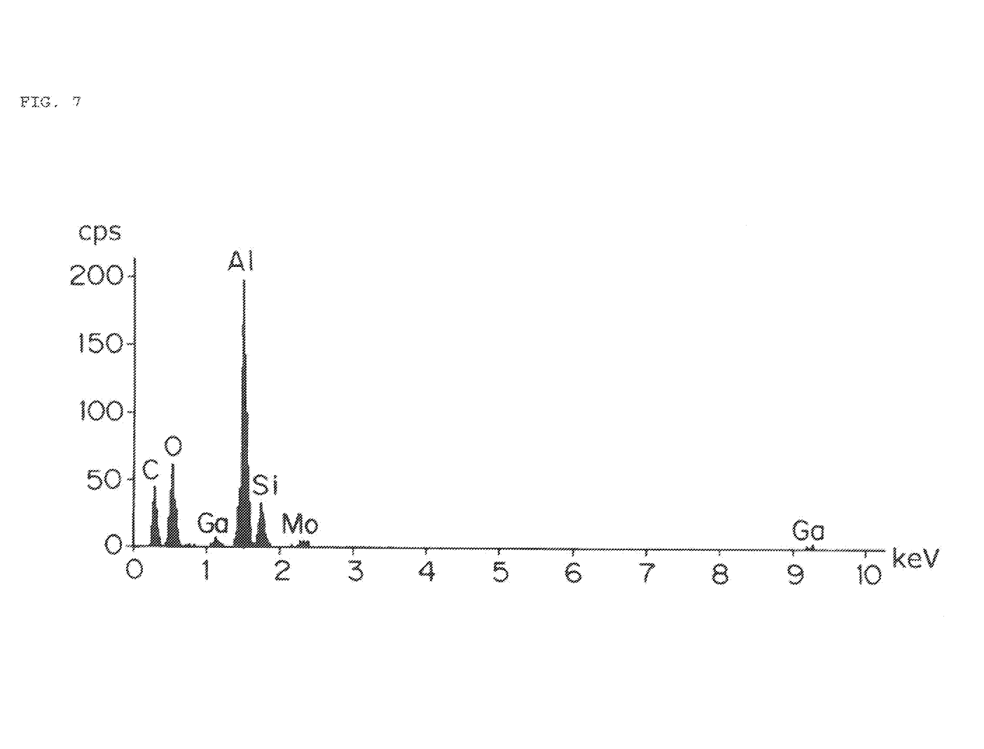

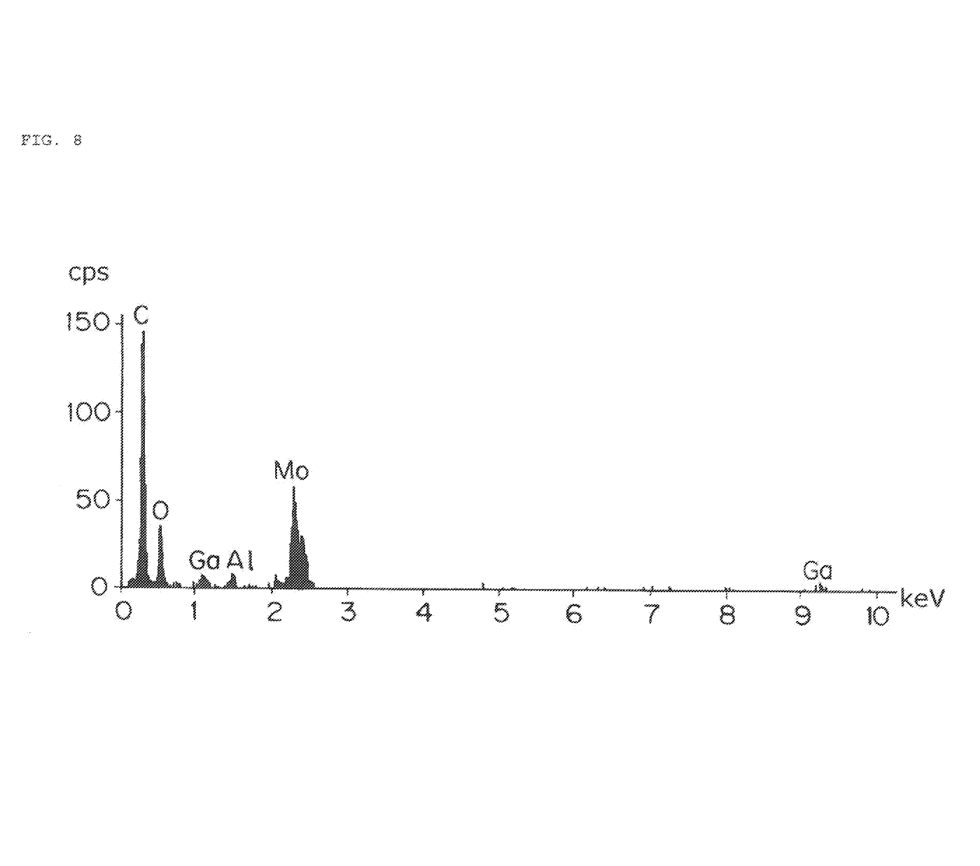

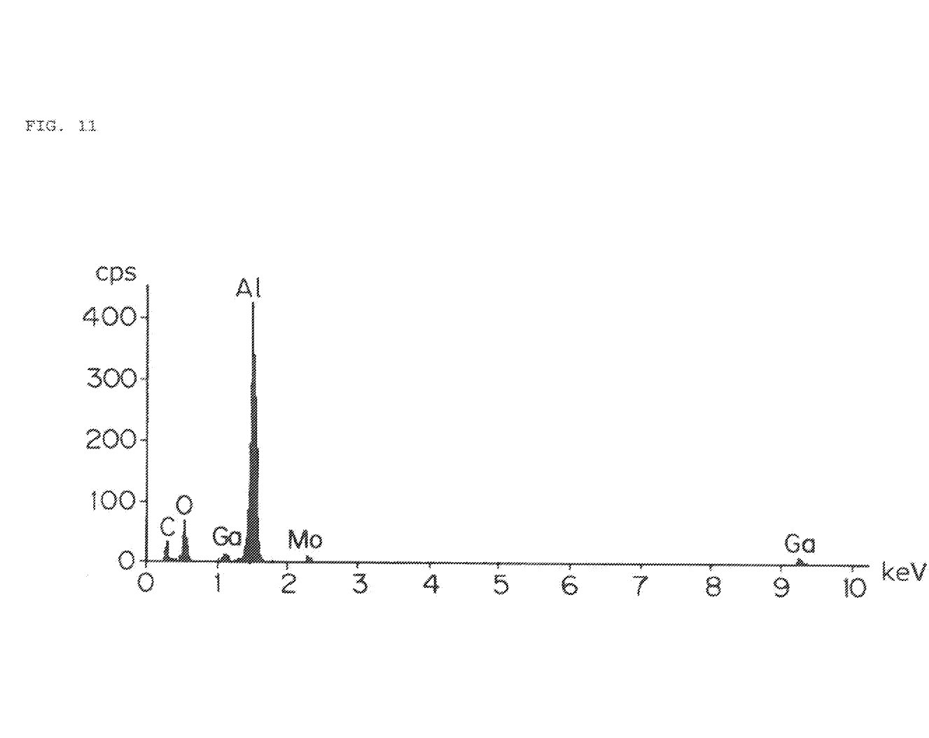

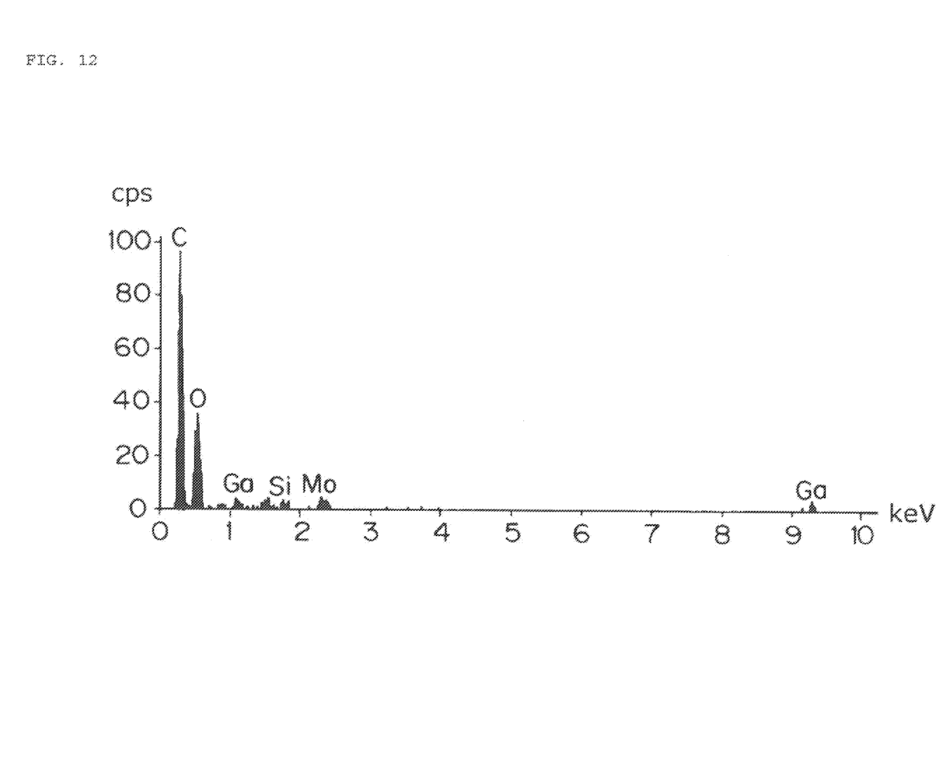

On the other hand, the point 1-2 in FIG. 5 corresponds to the mixed region 101 illustrated in FIG. 4(d). Moreover, the point 2-2 in FIG. 9 corresponds to the boundary between the work W and the Al thin film 102. There is the following difference: Si is detected at the point 1-2 (see FIG. 7), and on the other hand, Si is not detected at the point 2-2 (see FIG. 11). Note that the point 1-3 in FIG. 5 and the point 2-3 in FIG. 9 correspond to the work W, and components contained in the methacryl resin are detected (see FIGS. 8 and 12).

As described above, in the case of performing the film formation by the film formation method of the present invention, the mixed region 101 where Al, Si, O, and C are mixed together is formed between the work W made of the methacryl resin and the Al thin film 102. In the mixed region 101, Al is covalently bound to Si, O, and C, or Al, Si, O, and C form the diffusion mixed layer. Thus, the function of the mixed region 101 can prevent embrittlement due to broken molecular chains at the surface of the work W made of the methacryl resin. As a result, the work W made of the methacryl resin and the Al thin film 102 can be firmly stacked in close contact with each other.

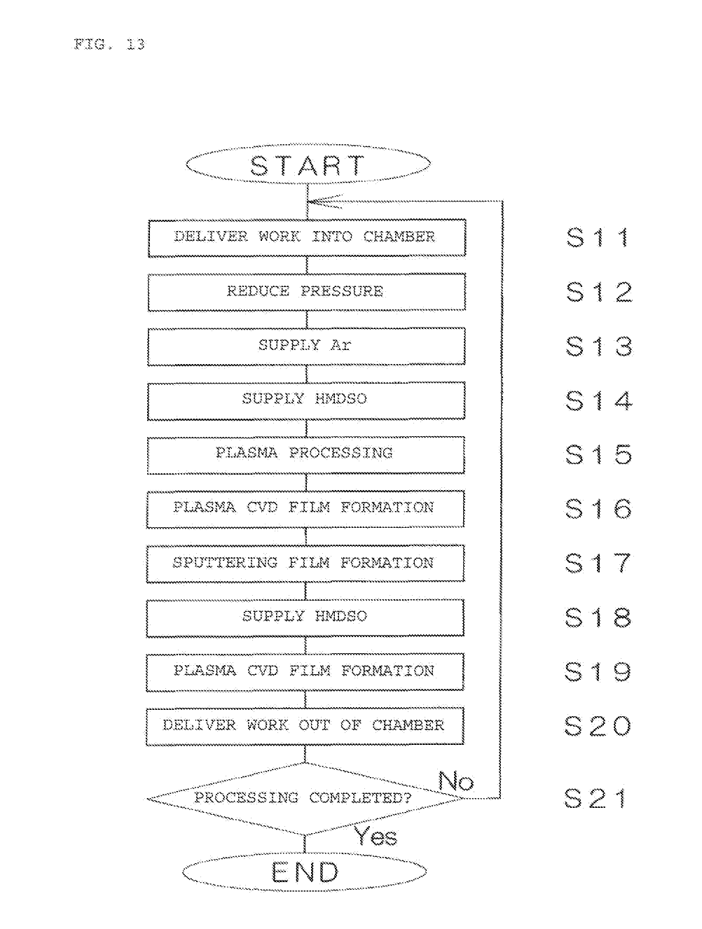

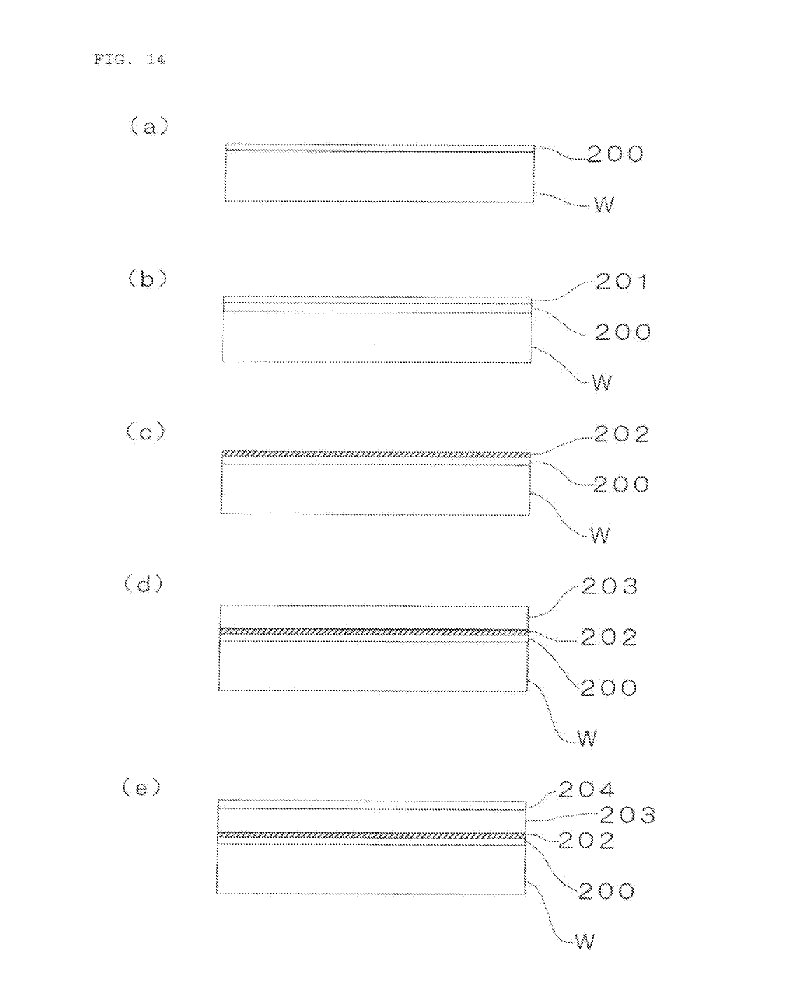

Next, another embodiment of the present invention will be described. FIG. 13 is a flowchart of film formation operation of a second embodiment. Moreover, FIGS. 14(a) to 14(e) are schematic views for the purpose of describing the state of film formation on a work W. Note that the second embodiment is different from the above-described embodiment in that the step of performing plasma CVD film formation using Si oxide is performed between a plasma processing step and a sputtering film formation step. In the following description, descriptions for the steps similar to those of the above-described embodiment will be simplified.

When the film formation operation of the second embodiment is performed, the injection-molded work W is delivered out of an injection molding machine, and then, is delivered into a film formation chamber 10 (step S11). Then, the inner pressure of the film formation chamber 10 is reduced to a low vacuum of about 0.1 to 1 pascal (step S12).

Next, an on-off valve 31 opens to supply argon as inert gas from an inert gas supply 33 into the film formation chamber 10, and then, the film formation chamber 10 is filled with the argon such that the degree of vacuum in the film formation chamber 10 reaches 0.5 to 3 pascals (step S13). Then, an on-off valve 34 opens to supply HMDSO from a raw material gas supply 36 into the film formation chamber 10 (step S14).

In this state, plasma processing is performed (step S15). At this point, a high-frequency voltage of about 400 W is applied from a high-frequency power source 45 to a CVD electrode 24 via a matching box 46. Moreover, HMDSO is supplied from the raw material gas supply 36 at a flow rate of about 5 sccm, and argon is supplied from the inert gas supply 33 at a flow rate of about 100 sccm. Such plasma processing is completed in about several tens of seconds. In this state, a mixed layer 200 of Si, O, and C generated from HMDSO etc. is formed on the surface of the work W made of methacryl resin, as illustrated in FIG. 14(a).

Next, plasma CVD film formation using Si oxide is performed (step S16). At this point, argon supply is stopped, and HMDSO is supplied from the raw material gas supply 36 at a flow rate of about 60 sccm. Then, a high-frequency voltage of about 500 W is applied from the high-frequency power source 45 to the CVD electrode 24 via the matching box 46. Such plasma CVD film formation processing is completed in about 10 seconds.

In the plasma CVD film formation step using Si oxide, HMDSO is decomposed using plasma as an energy source, and Si oxide (SiOx where x=1 to 2) is deposited by chemical reaction. Thus, a Si oxide layer 201 is formed on the surface of the mixed layer 200, as illustrated in FIG. 14 (b). The thickness of the Si oxide layer 201 is about several nanometers to about two micrometers.

Next, sputtering film formation is performed (step S17). At this point, as indicated by the virtual line of FIG. 1, the work W mounted on a work mount 13 is moved to face a sputtering electrode 23 in the film formation chamber 10. Moreover, as indicated by the solid line of FIG. 1, a shutter 51 is at the retracted position in the vicinity of a bottom portion of the film formation chamber 10. In the case of performing the sputtering film formation, direct current voltage is applied from a direct current power source 41 to the sputtering electrode 23. Thus, a thin film 203 of Al as a target material 22 is formed on the surface of the work W by the sputtering phenomenon.

In the above-described state, Al first contacts, by the sputtering phenomenon, the Si oxide layer 201. Thus, as illustrated in FIG. 14(c), Al is covalently bound to Si and O in part of the Si oxide layer 201, or Al, Si and O form a diffusive mixed layer in part of the Si oxide layer 201. Thus, a mixed region 202 where Al, Si and O are mixed together is formed. At this point, the thickness of the mixed region 202 is about several angstroms to about several nanometers equivalent to about several atomic layers.

By continuing the sputtering film formation, the Al thin film 203 is formed on the mixed region 202 as illustrated in FIG. 14(d). The thickness of the Al thin film 203 is about 150 nanometers.

Note that at this sputtering film formation step, direct current voltage is applied from the direct current power source 41 to the sputtering electrode 23 such that a power of equal to or higher than 25 watts is applied to every square centimeter of the surface area of the target material 22 of the sputtering electrode 23. Thus, even in the case of a low vacuum in the film formation chamber 10, the Al thin film 203 is suitably formed on the surface of the resin work W.

After the sputtering film formation performed by the above-described steps has been completed, the plasma CVD film formation using Si oxide is subsequently performed. At this point, as indicated by the solid line of FIG. 1, the work W mounted on the work mount 13 is moved to face the CVD electrode 24 in the film formation chamber 10. Moreover, as indicated by the virtual line of FIG. 1, the shutter 51 is at the contact position at which the shutter 51 contacts the sputtering electrode 23 to cover the target material 22.

In this state, the on-off valve 34 opens to supply HMDSO as raw material gas from the raw material gas supply 36 into the film formation chamber 10, and as a result, the degree of vacuum in the film formation chamber 10 reaches 0.1 to 10 pascals (step S18). Then, high-frequency voltage is applied from the high-frequency power source 45 to the CVD electrode 24 via the matching box 46, and therefore, the plasma CVD film formation is performed (step S19). As illustrated in FIG. 14(e), a protection film 204 is, as a result of the plasma CVD reaction using the raw material gas, deposited on the surface of the work W (i.e., the surface of the Al thin film 203).

After the plasma CVD film formation has been completed, the film formation chamber 10 is vented. Subsequently, the work mount 13 is moved with an openable portion 12 being at the delivery position, and then, the work W mounted on the work mount 13 is, after the film formation, delivered out of the film formation chamber 10 (step S20).

Then, it is determined whether or not the processing for all of the works W has been completed (step S21). When the processing for all of the works W has been completed, the device is stopped. On the other hand, when there is an unprocessed work(s) W, the process returns to step S11.

In the case of performing film formation by the film formation method of the second embodiment, embrittlement due to broken molecular chains at the surface of the work W made of the methacryl resin can be prevented. As a result, the work W made of the methacryl resin and the Al thin film 203 can be firmly stacked in close contact with each other.

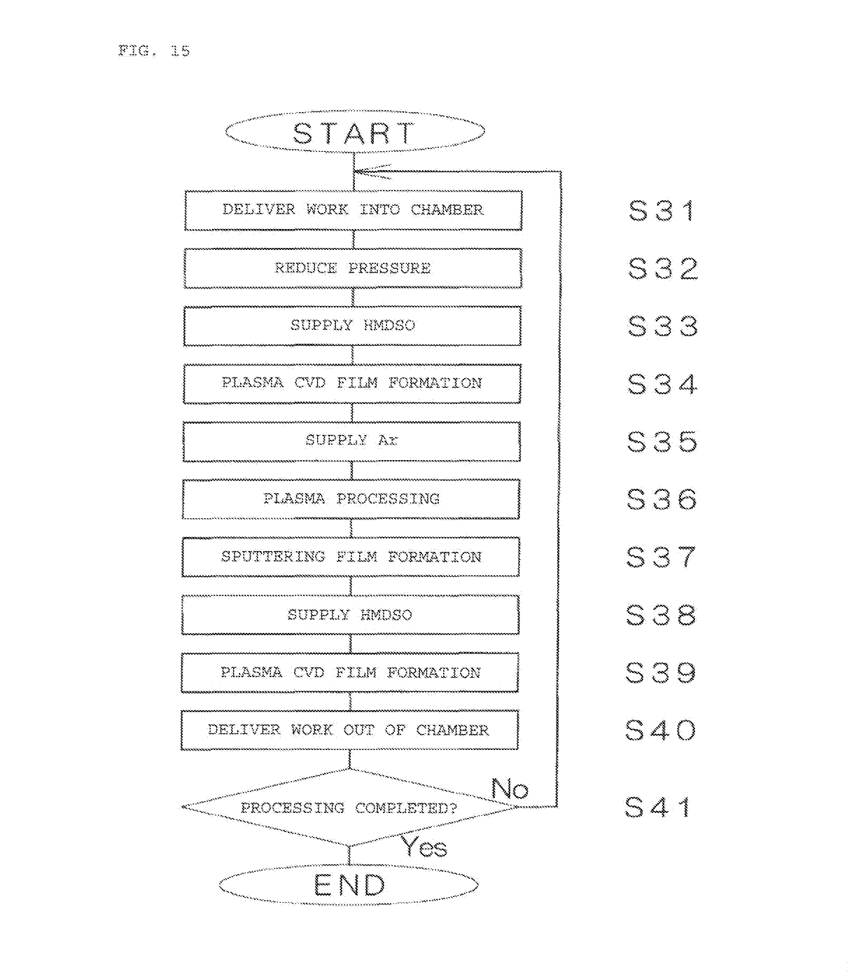

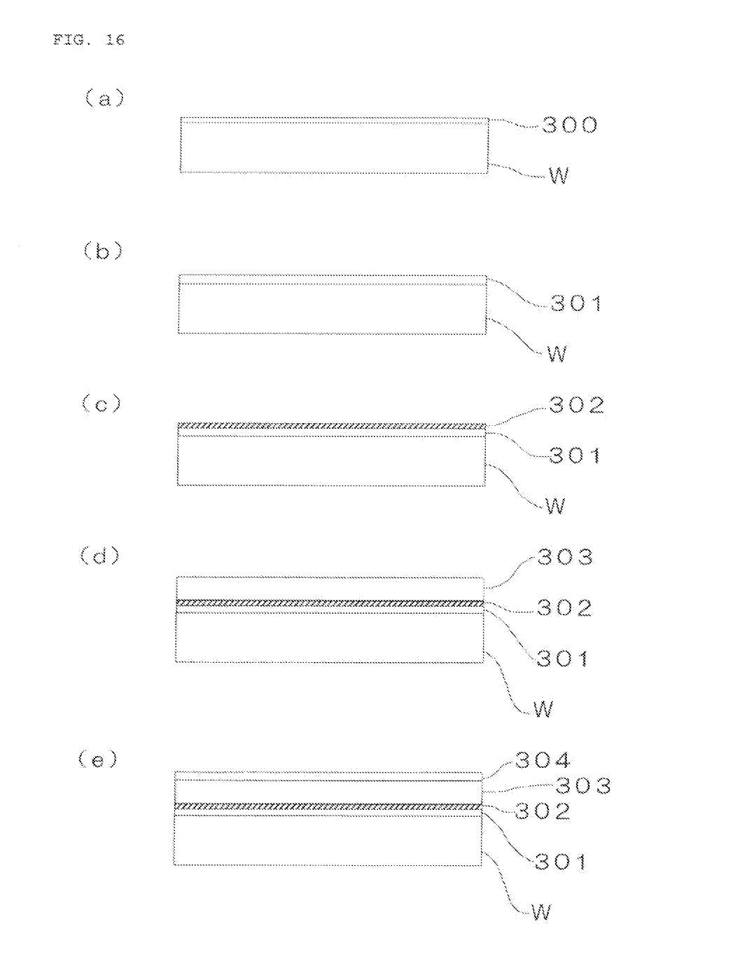

Next, still another embodiment of the present invention will be described. FIG. 15 is a flowchart of film formation operation of a third embodiment. Moreover, FIGS. 16(a) to 16(e) are schematic views for the purpose of describing the state of film formation on a work W. Note that in the third embodiment, the plasma processing step and the plasma CVD film formation step using Si oxide in the second embodiment are performed in the reverse order. That is, in the case where the thickness of the Si oxide film formed at the plasma CVD film formation step using Si oxide is equal to or less than several tens of nanometers, the advantageous effects similar to those of the second embodiment can be provided even if the plasma processing step is performed after the plasma CVD film formation step using Si oxide.

When the film formation operation of the third embodiment is performed, the injection-molded work W is delivered out of an injection molding machine, and then, is delivered into a film formation chamber 10 (step S31). Then, the inner pressure of the film formation chamber 10 is reduced to a low vacuum of about 0.1 to 1 pascal (step S32).

Next, plasma CVD film formation using Si oxide is performed. At this point, HMDSO is supplied from a raw material gas supply 36 at a flow rate of about 60 sccm (step S33). Then, a high-frequency voltage of about 500 W is applied from a high-frequency power source 45 to a CVD electrode 24 via a matching box 46 (step S34). Such plasma CVD film formation processing is completed in about 10 seconds.

In the plasma CVD film formation step using Si oxide, HMDSO is decomposed using plasma as an energy source, and Si oxide (SiOx where x=1 to 2) is deposited by chemical reaction. Thus, a Si oxide layer 300 is formed on the surface of the work W made of methacryl resin, as illustrated in FIG. 16(a). The thickness of the Si oxide layer 300 is equal to or less than several tens of nanometers.

Next, an on-off valve 31 opens to supply argon as inert gas from an inert gas supply 33 into the film formation chamber 10, and then, the film formation chamber 10 is filled with the argon such that the degree of vacuum in the film formation chamber 10 reaches 0.5 to 3 pascals (step S35).

In this state, plasma processing is performed (step S36). At this point, a high-frequency voltage of about 400 W is applied from the high-frequency power source 45 to the CVD electrode 24 via the matching box 46. Moreover, HMDSO is supplied from the raw material gas supply 36 at a flow rate of about 5 sccm, and argon is supplied from the inert gas supply 33 at a flow rate of about 100 sccm. Such plasma processing is completed in about several tens of seconds. In this state, the Si oxide layer 300 formed at the previous plasma CVD film formation step (step S34) as illustrated in FIG. 16(a) and having a thickness of equal to or less than several tens of nanometers is replaced with a mixed layer 301 of Si, O, and C as illustrated in FIG. 16(b).

Next, sputtering film formation is performed (step S37). At this point, as indicated by the virtual line of FIG. 1, the work W mounted on a work mount 13 is moved to face a sputtering electrode 23 in the film formation chamber 10. Moreover, as indicated by the solid line of FIG. 1, a shutter 51 is at the retracted position in the vicinity of a bottom portion of the film formation chamber 10. In the case of performing the sputtering film formation, direct current voltage is applied from a direct current power source 41 to the sputtering electrode 23. Thus, a thin film 303 of Al as a target material 22 is formed on the surface of the work W by the sputtering phenomenon.

In the above-described state, Al first contacts, by the sputtering phenomenon, the mixed layer 301 of Si, O, and C. Thus, as illustrated in FIG. 16(c), Al is covalently bound to Si, C, and O in part of the mixed layer 301 of Si, O, and C, or Al, Si, C, and O form a diffusion mixed layer in part of the mixed layer 301 of Si, O, and C. Thus, a mixed region 302 where Al, Si, C, and O are mixed together is formed. At this point, the thickness of the mixed region 302 is about several angstroms to about several nanometers equivalent to about several atomic layers.

By continuing the sputtering film formation, the Al thin film 303 is formed on the mixed region 302 as illustrated in FIG. 16(d). The thickness of the Al thin film 303 is about 150 nanometers.

Note that at this sputtering film formation step, direct current voltage is applied from the direct current power source 41 to the sputtering electrode 23 such that a power of equal to or higher than 25 watts is applied to every square centimeter of the surface area of the target material 22 of the sputtering electrode 23. Thus, even in the case of a low vacuum in the film formation chamber 10, the Al thin film 303 is suitably formed on the surface of the resin work W.

After the sputtering film formation performed by the above-described steps has been completed, plasma CVD film formation using Si oxide is subsequently performed. At this point, as indicated by the solid line of FIG. 1, the work W mounted on the work mount 13 is moved to face the CVD electrode 24 in the film formation chamber 10. Moreover, as indicated by the virtual line of FIG. 1, the shutter 51 is at the contact position at which the shutter 51 contacts the sputtering electrode 23 to cover the target material 22.

In this state, an on-off valve 34 opens to supply HMDSO as raw material gas from the raw material gas supply 36 into the film formation chamber 10, and as a result, the degree of vacuum in the film formation chamber 10 reaches 0.1 to 10 pascals (step S38). Then, high-frequency voltage is applied from the high-frequency power source 45 to the CVD electrode 24 via the matching box 46, and therefore, the plasma CVD film formation using Si oxide is performed (step S39). As illustrated in FIG. 16(e), a protection film 304 is, as a result of the plasma CVD reaction using the raw material gas, deposited on the surface of the work W (i.e., the surface of the Al thin film 303).

After the plasma CVD film formation using Si oxide has been completed, the film formation chamber 10 is vented. Subsequently, the work mount 13 is moved with an openable portion 12 being at the delivery position, and then, the work W mounted on the work mount 13 is, after the film formation, delivered out of the film formation chamber 10 (step S40).

Then, it is determined whether or not the processing for all of the works W has been completed (step S41). When the processing for all of the works W has been completed, the device is stopped. On the other hand, when there is an unprocessed work(s) W, the process returns to step S11.

In the case of performing film formation by the film formation method of the third embodiment, embrittlement due to broken molecular chains at the surface of the work W made of the methacryl resin can be prevented. As a result, the work W made of the methacryl resin and the Al thin film 303 can be firmly stacked in close contact with each other.

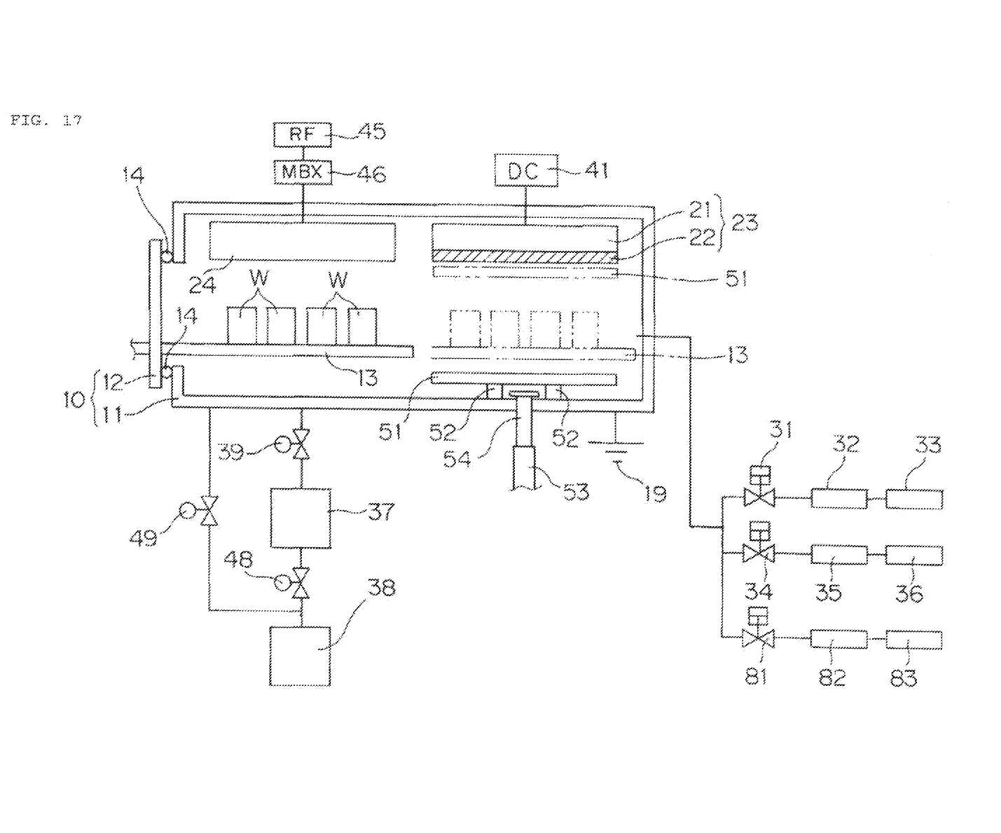

Next, still another embodiment of the present invention will be described. FIG. 17 is a schematic diagram of a film formation device configured to perform a film formation method of a fourth embodiment of the present invention. Note that the same reference numerals as those in the film formation device of FIG. 1 are used to represent equivalent elements in FIG. 17, and detailed description thereof will not be repeated.

In the film formation method of the fourth embodiment, oxygen is supplied instead of supplying argon at steps S3 to S5 of the film formation method of the first embodiment described above. The film formation device configured to perform the film formation method of the fourth embodiment is, as illustrated in FIG. 17, configured such that an on-off valve 81, a flow control valve 82, and an oxygen supply 83 are added to the film formation device of FIG. 1.

In the film formation method of the first embodiment, an undecomposed portion of HMDS might be, due to an excessive amount of HMDSO supply or depending on the extent of contamination in the device, non-uniformly recombined and deposited on the surface of the methacryl resin. For this reason, a normal reflectance might be lowered as compared to a normal reflectance prior to the processing due to an increase in a surface roughness. For this reason, in the film formation method of the fourth embodiment, a gas species is changed from argon to oxygen.

In the case where the plasma processing using oxygen is performed instead of the plasma processing using argon as described above, HMDSO is fully decomposed, and Si oxide (SiOx where x=1 to 2) containing no alkyl group is deposited thinly on the surface of the methacryl resin. This prevents attack by an active species in oxygen plasma, and therefore, the surface roughness of the methacryl resin is not increased. Moreover, moisture adhering to the surface of the methacryl resin is removed by the plasma processing in high-speed exhausting, and oxidation of the sputtering film in the subsequent processing is reduced. As a result, a reflectance improvement effect is also provided.

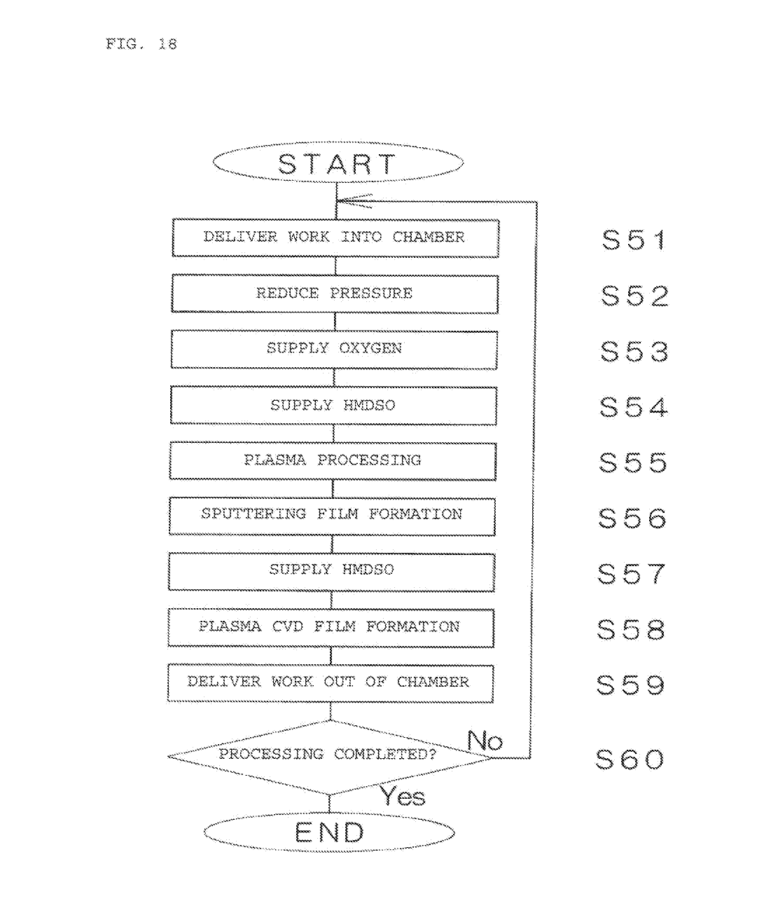

FIG. 18 is a flowchart of film formation operation of the fourth embodiment of the present invention. Note that descriptions for the steps similar to those of the film formation operation of the first embodiment described above will be simplified below.

When the film formation operation is performed by the film formation method of the fourth embodiment, an injection-molded work W is delivered out of an injection molding machine, and then, is delivered into a film formation chamber 10 (step S51). Then, the inner pressure of the film formation chamber 10 is reduced to a low vacuum of about 0.1 to 1 pascal (step S52).

Next, the on-off valve 81 opens to supply oxygen from the oxygen supply 83 into the film formation chamber 10, and then, the film formation chamber 10 is filled with the oxygen such that the degree of vacuum in the film formation chamber 10 reaches 0.5 to 3 pascals (step S53). Then, an on-off valve 34 opens to supply HMDSO from a raw material gas supply 36 into the film formation chamber 10 (step S54).

In this state, plasma processing is performed (step S55). At this point, a high-frequency voltage of about 400 W is applied from a high-frequency power source 45 to a CVD electrode 24 via a matching box 46. Moreover, HMDSO is supplied from the raw material gas supply 36 at a flow rate of about 5 sccm, and oxygen is supplied from the oxygen supply 83 at a flow rate of about 100 sccm. Such plasma processing is completed in about several tens of seconds.

Next, sputtering film formation is performed (step S56). After the sputtering film formation has been completed, plasma CVD film formation using Si oxide is subsequently performed. At this point, HMDSO as raw material gas is supplied into the film formation chamber 10 such that the degree of vacuum in the film formation chamber 10 reaches 0.1 to 10 pascals (step S57). Then, high-frequency voltage is applied to the CVD electrode 24, and in this manner, the plasma CVD film formation is performed (step S58). Subsequently, the work W is, after the film formation, delivered out of the film formation chamber 10 (step S59). It is determined whether or not the processing for all of the works W has been completed (step S10). When the processing for all of the works W has been completed, the device is stopped. On the other hand, when there is an unprocessed work(s) W, the process returns to step S51.

Note that in the film formation method of the fourth embodiment described above, oxygen is supplied instead of supplying argon at steps S3 to S5 of the film formation method of the first embodiment. Similarly, oxygen may be supplied instead of supplying argon at steps S13 to S15 of the film formation method of the second embodiment. Moreover, oxygen may be supplied instead of supplying argon at steps S35 to S36 of the film formation method of the third embodiment.

In any of the above-described embodiments, the case where the present invention is applied to the film formation device configured to continuously perform the sputtering film formation and the plasma CVD film formation in the same film formation chamber 10 has been described. However, the present invention is applicable to a film formation device configured to perform only sputtering film formation.

### DESCRIPTION OF REFERENCE SIGNS

10 film formation chamber
11 main body
12 openable portion
13 work mount
19 ground
21 electrode portion
22 target material
23 sputtering electrode
24 CVD electrode
31 on-off valve
32 flow control valve
33 inert gas supply
34 on-off valve
35 flow control valve
36 raw material gas supply
37 turbo-molecular pump
38 auxiliary pump
39 on-off valve
41 direct current power source
45 high-frequency power source
46 matching box
48 on-off valve
49 on-off valve
51 shutter
70 controller
71 delivery mechanism driver
72 on-off valve driver
73 openable portion driver
74 electrode driver
81 on-off valve
82 flow control valve
83 oxygen supply
100 compound layer
101 mixed region
102 Al thin film
103 protection film
200 mixed layer
201 Si oxide layer
202 mixed region
203 Al thin film
204 protection film
300 Si oxide layer
301 mixed layer
302 mixed region
303 Al thin film
304 protection film
W work

1.-16. (canceled)

17. A structure in which resin and a metal thin film are stacked one another, comprising:
a mixed region
which is formed between the resin and the metal thin film, and
in which atoms forming the metal thin film are covalently bound to Si, or the atoms forming the metal thin film and Si form a diffusion mixed layer.

18. The structure according to claim 17, wherein
in the mixed region,
at least one of O and C is mixed in addition to the atoms forming the metal thin film and Si, and
the atoms forming the metal thin film are covalently bound to any one of Si, O, and C, or the atoms forming the metal thin film and any one of Si, O, and C form the diffusion mixed layer.

19. A structure in which resin and a metal thin film are stacked one another, wherein
a mixed layer of Si, O, and C, a compound layer containing Si oxide, and a mixed region of atoms forming the metal thin film, Si, and O are, in this order, stacked one another between the resin and the metal thin film.

20. The structure according to claim 19, wherein
in the mixed region,
the atoms forming the metal thin film are covalently bound to Si and O, or
the atoms forming the metal thin film, Si, and O form a diffusion mixed layer.

21. A structure in which resin and a metal thin film are stacked one another, wherein
a mixed layer of Si, O, and C and a mixed region of atoms forming the metal thin film, Si, O, and C are, in this order, stacked one another between the resin and the metal thin film.

22. The structure according to claim 21, wherein
in the mixed region,
the atoms forming the metal thin film are covalently bound to Si, O and C, or
the atoms forming the metal thin film, Si, O, and C form a diffusion mixed layer.

23. The structure according to claim 17, wherein
the resin is methacryl resin.

24. The structure according to claim 17, wherein
the metal thin film is formed of Al or metal containing Al as a main component.

25. The structure according to claim 17, wherein
a protection film is further formed on a surface of the metal thin film.

26. The structure according to claim 25, wherein
the protection film is a Si oxide-based protection film.

27. A method for forming a metal thin film on a resin work, comprising:
a step of performing plasma processing for the rein work under a presence of Si to form a Si layer on the work;
a step of performing sputtering film formation for the work using a metal target material, thereby performing the sputtering film formation for the Si layer to form a mixed region in which atoms forming the metal thin film are covalently bound to Si or the atoms forming the metal thin film and Si form a diffusion mixed layer; and
a step of using the metal target material to continuously perform the sputtering film formation for the work, thereby forming the metal thin film on the mixed region.

28. A method for forming a metal thin film on a resin work, comprising:
a step of performing plasma processing for the rein work under a presence of Si to form a mixed layer of Si, O, and C on the work;
a step of continuously performing plasma CVD using a supplied raw material of Si, thereby forming a Si oxide layer on the mixed layer;
a step of using a metal target material to perform sputtering film formation for the work, thereby performing the sputtering film formation for the Si oxide layer to form a mixed region in which atoms forming the metal thin film are covalently bound to Si and O or the atoms forming the metal thin film, Si, and O form a diffusion mixed layer; and
a step of using the metal target material to continuously perform the sputtering film formation for the work, thereby forming the metal thin film on the mixed region.

29. A method for forming a metal thin film on a resin work, comprising:
a step of performing plasma CVD using a supplied raw material containing Si, thereby forming a Si oxide layer on the work;
a step of continuously performing plasma processing for the resin work under a presence of Si, thereby replacing the Si oxide layer with a mixed layer of Si, O, and C on the work;
a step of using a metal target material to continuously perform sputtering film formation for the work, thereby performing the sputtering film formation for the mixed layer to form, in an upper portion of the mixed layer, a mixed region in which atoms forming the metal thin film are covalently bound to Si, O, and C or the atoms forming the metal thin film, Si, O, and C form a diffusion mixed layer; and
a step of using the metal target material to continuously perform the sputtering film formation for the work, thereby forming the metal thin film on the mixed region.

30. The method according to claim 27, wherein
the plasma processing is performed in a state in which oxygen is supplied.

31. The method according to claim 27, wherein
the sputtering film formation is performed with a power of equal to or higher than 25 watts per square centimeter of a surface area of a target.

32. The method according to claim 28, wherein
the plasma processing is performed in a state in which oxygen is supplied.

33. The method according to claim 28, wherein
the sputtering film formation is performed with a power of equal to or higher than 25 watts per square centimeter of a surface area of a target.

34. The method according to claim 29, wherein
the plasma processing is performed in a state in which oxygen is supplied.

35. The method according to claim 29, wherein
the sputtering film formation is performed with a power of equal to or higher than 25 watts per square centimeter of a surface area of a target.
